(19) United States
(12) Patent Application Publication
(10) Pub. No.: US 2014/0357083 A1
(43) Pub. Date: Dec. 4, 2014

(54) DIRECTED BLOCK COPOLYMER SELF-ASSEMBLY PATTERNS FOR ADVANCED PHOTOLITHOGRAPHY APPLICATIONS

(71) Applicant: APPLIED MATERIALS, INC., Santa Clara, CA (US)

(72) Inventors: Mang-Mang LING, Sunnyvale, CA (US); Lina ZHU, San Jose, CA (US); Nancy FUNG, Livermore, CA (US); Kwang-Soo KIM, Santa Clara, CA (US); Sean S. KANG, San Ramon, CA (US); Srinivas D. NEMANI, Sunnyvale, CA (US)

(73) Assignee: APPLIED MATERIALS, INC., Santa Clara, CA (US)

(21) Appl. No.: 14/283,694

(22) Filed: May 21, 2014

Related U.S. Application Data
(60) Provisional application No. 61/829,761, filed on May 31, 2013.

(51) Int. Cl. H01L 21/311; H01L 21/3065

(52) U.S. Cl. CPC H01L 21/31138; H01L 21/3065
USPC 438/694; 438/725

(57) ABSTRACT

Embodiments of methods and an apparatus for utilizing a directed self-assembly (DSA) process on block copolymers (BCPs) to form a defect-free photoresist layer for feature transfer onto a substrate are provided. In one embodiment, a method for performing a dry development process includes transferring a substrate having a layer of block copolymers disposed thereon into an etching processing chamber, wherein at least a first type and a second type of polymers comprising the block copolymers are aggregated into a first group of regions and a second group of regions on the substrate, supplying an etching gas mixture including at least a carbon containing gas into the etching processing chamber, and predominately etching the second type of the polymers disposed on the second groups of regions on the substrate in the presence of the etching gas mixture.

### CROSS-REFERENCE TO RELATED APPLICATION

This application claims benefit of U.S. Provisional Application Ser. No. 61/829,761 filed May 31, 2013 (Attorney Docket No. APPM/20778L), which is incorporated by reference in its entirety.

### BACKGROUND

1. Field

Embodiments generally relates to methods and apparatus for forming devices using lithography, more specifically, to methods and apparatus for forming devices using directed self-assembled (DSA) block copolymers (BCPs) as a photoresist layer in semiconductor processing technologies are provided.

2. Description of the Related Art

Integrated circuits have evolved into complex devices that can include millions of components (e.g., transistors, capacitors and resistors) on a single chip. The evolution of chip designs continually requires faster circuitry and greater circuit density. The demands for greater circuit density necessitate a reduction in the dimensions of the integrated circuit components.

As the dimensions of the integrated circuit components are reduced (e.g. to sub-micron dimensions), more elements are required to be put in a given area on a semiconductor integrated circuit. Accordingly, lithography process has become more and more challenging to transfer even smaller features onto a substrate precisely and accurately without damage. In order to transfer precise and accurate features onto a substrate, a desired high resolution lithography process requires having a suitable light source that may provide a radiation at a desired wavelength range for exposure. Furthermore, the lithography process requires transferring features onto a photoresist layer with minimum defects, such as photoresist line width roughness (LWR). After all, a defect-free photoresist layer is required to precisely transfer desired features onto the substrate. Recently, imprint lithography has been widely used and utilizes a template to transfer patterns onto a substrate. An advantage of imprint lithograph is that the resolution of the features is not limited by, for example, the emission wavelength of a radiation source or the numerical aperture of a projection system. In particular, the use of directed self-assembly (DSA) of block copolymers (BCPs) as a photoresist layer during a lithography process has been considered as a potential method for improving the resolution for the lithography process as the block copolymers (BCPs) may self-assemble into distinct domains with dimensions in the tens of nanometers or lower.

FIG. 1A-1F depict an example of top isometric sectional view of a substrate 100 over a sequence of utilizing a directed self-assembly (DSA) of block copolymers (BCPs) process to form features on the substrate 100. The substrate 100 may have a patterning defining layer 102 disposed thereon providing an exposed surface 104, as shown in FIG. 1A. In one embodiment, the patterning defining layer 102 may be an anti-reflective coating (ARC) layer or other suitable layers as needed. Subsequently, a light activation process may be performed to direct a light 106 onto a first region 108 on the exposed surface 104 of the patterning defining layer 102, as shown in FIG. 1B. The light 106 directed onto the substrate 100 creates mileposts or markers 109 in the treated region 108 of the patterning defining layer 102, as shown in FIG. 1C. The mileposts or markers 109 and un-treated region 110 created and defined in the patterning defining layer 102 provide guidance to a layer of block copolymers (BCPs) 112 subsequently deposited thereon for segregation based on dissimilarities of polymers included in the layer of block copolymers (BCPs) 112 during the subsequent directed self-assembly (DSA) process, as shown in FIG. 1D. For example, the light activation process may alter the film properties of the treated region 108 from non-polar to polar, oil-like to water-like, hydrophobic to hydrophilic, or vice versa; or alter the surface roughness or change the topography, such as forming a shallow trench. These changes may promote to the block copolymers (BCPs) 112 to have a shift in phase orientation shift during the directed self-assembly (DSA) process.

In one embodiment, the layer of block copolymers (BCPs) 112 may include two or more dissimilar polymeric block components. The block components are derived from different chemical monomers with dissimilar chemical properties and bonding structures. For example, a block copolymer can comprise a first block component labeled as polymer A and a second block component labeled as polymer B, represented by the formula (AB)ₙ, wherein the n is any integer greater than or equal to 1.

An annealing process is then performed on the substrate 100. The thermal energy provided from the annealing process provides dynamic energy to trigger the block copolymers (BCPs) in the layer 112 undergo phase orientation changes. Microphase separation between the two dissimilar polymers occurs so that two blocks 118, 116 of polymers form line strips of different monomers that spontaneously self-assemble into nano-scale domains that exhibit ordered morphology based on the guidance from the mileposts or markers 109 and unemitted region 110 created on the patterning defining layer 102, as shown in FIG. 1E. In the embodiment depicted in FIG. 1E, two different polymers, polymer A and polymer B, are then segregated and formed in separated blocks 116, 118 in form of strip lines on the substrate 100.

Subsequently, a development process, wet or dry, may be performed to remove one type of polymer, either polymer A or polymer B, from the substrate 100, forming openings 122 between the remaining polymer to expose the underlying patterning defining layer 102 for pattern/feature transfer. In the exemplary embodiment depicted in FIG. 1F, the polymer B in form of the strip line block 116 is removed, leaving the polymer A in form of the strip line block 118 on the substrate 100 as an etching mask to transfer features into the substrate 100. In some situations, chemical try development process has been tested to remove the strip line block 118. However, inaccurate control or inadequate selection of chemistries for the dry development process may result in poor critical dimension of the formed strip line block 118. Furthermore, poor selectivity between the strip line block 118 and the strip line block 116 may also result in poor profile control and inaccurate critical dimension after etching. These unwanted defects may result in inaccurate feature transfer to the substrate 100, thus, eventually leading to device failure and yield loss.

Therefore, there is a need for a method and an apparatus to perform a dry development process to form patterned photoresist layer on a substrate with desired critical dimensions and profile.

### SUMMARY

Embodiments of methods and an apparatus for performing a dry development process utilizing a directed self-assembly (DSA) process on block copolymers (BCPs) to form a defect-free patterned photoresist layer for feature transfer onto a substrate are provided. In one embodiment, a method for performing a dry development process includes transferring a substrate having a layer of block copolymers disposed thereon into an etching processing chamber, wherein at least a first type and a second type of polymers comprising the block copolymers are aggregated into a first group of regions and a second group of regions on the substrate, supplying an etching gas mixture including at least a carbon containing gas into the etching processing chamber, and predominately etching the second type of the polymers disposed on the second groups of regions on the substrate in the presence of the etching gas mixture.

In another embodiment, a method for forming a photoresist layer using a directed self-assembly process includes disposing a layer of block copolymers on a substrate, wherein the block copolymers include at least a first type of polymer and a second type of polymer, performing an annealing process on the layer of block copolymers, the annealing process separating the first type of polymer from the second type of the polymer, supplying an etching gas mixture including at least a carbon containing gas onto the substrate, and selectively etching the second type of polymer in the presence of the etching gas mixture.

In yet another embodiment, a method for forming a photoresist layer by a dry development process utilizing a directed self-assembly of block copolymers process includes forming a layer of block copolymers including polystyrene and polymethylmethacrylate on a substrate wherein the polystyrene and the polymethylmethacrylate are formed in strip line forms and separately arranged in a first group and a second group of regions defined on the substrate, supplying an etching gas mixture including at least a carbon containing gas, applying a RF bias power no more than 70 Watts, and selectively etching the polymethylmethacrylate disposed on the second groups of region from the substrate in the presence of the etching gas mixture.

### BRIEF DESCRIPTION OF THE DRAWINGS

So that the manner in which the above recited features of embodiments as described are attained and can be understood in detail, a more particular description of the embodiments, briefly summarized above, may be had by reference to the embodiments thereof which are illustrated in the appended drawings.

FIGS. 1A-1F depicts a sequence for forming a photoresist layer using a conventional directed self-assembly (DSA) of block copolymers (BCPs) process;

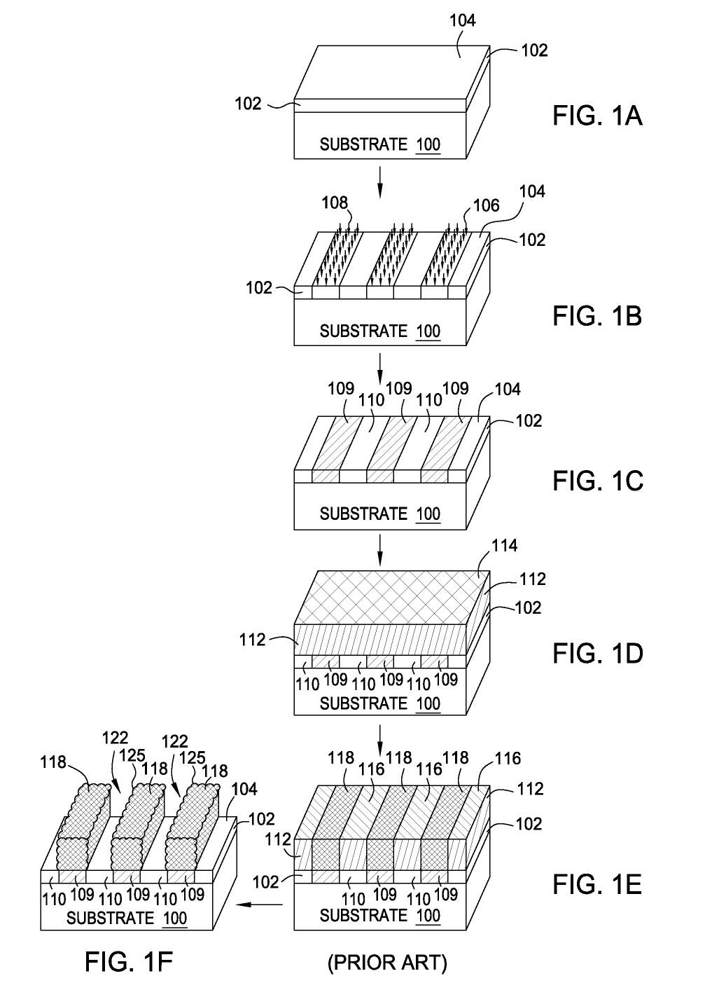

FIG. 2 depicts an apparatus utilized to form a photoresist layer using a directed self-assembly (DSA) of block copolymers (BCPs) process in accordance with one embodiment;

FIG. 3 depicts a flow diagram of a method for forming a photoresist layer using a directed self-assembly (DSA) of block copolymers (BCPs) process in accordance with one embodiment; and

FIG. 4A-4D depict one embodiment of a sequence for manufacturing forming a photoresist layer using a directed self-assembly (DSA) of block copolymers (BCPs) process in accordance with the embodiment depicted in FIG. 3.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments and are therefore not to be considered limiting of its scope, may admit to other equally effective embodiments.

### DETAILED DESCRIPTION

Embodiments of methods and apparatus for forming a patterned photoresist layer on a substrate to transfer features into the substrate using a directed self-assembly (DSA) of block copolymers (BCPs) process are included herein. In one embodiment, a dry development process is utilized to form a patterned photoresist layer using the directed self-assembly (DSA) of block copolymers (BCPs) process. The dry development process includes utilizing a gas mixture including at least a carbon containing gas to predominantly remove a type of polymer from the block copolymers, forming a patterned photoresist layer with desired profile on the substrate.

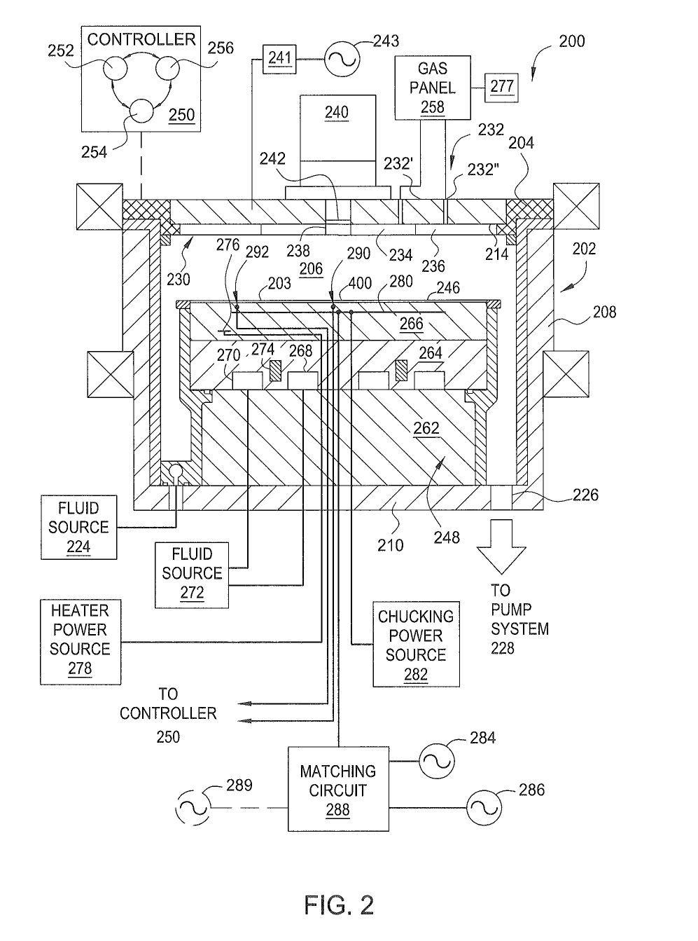

FIG. 2 is a sectional view of one embodiment of a processing chamber 200 suitable for performing an dry development process to form a patterned photoresist layer on a substrate using a directed self-assembly (DSA) of block copolymers (BCPs) process. Suitable processing chambers that may be adapted for use with the teachings disclosed herein include, for example, a modified ENABLER® processing chamber available from Applied Materials, Inc. of Santa Clara, Calif. Although the processing chamber 200 is shown including a plurality of features that enable superior etching and trimming performance, it is contemplated that other processing chambers may be adapted to benefit from one or more of the inventive features disclosed herein.

The processing chamber 200 includes a chamber body 202 and a lid 204 which enclose an interior volume 206. The chamber body 202 is typically fabricated from aluminum, stainless steel or other suitable material. The chamber body 202 generally includes sidewalls 208 and a bottom 210. A substrate support pedestal access port (not shown) is generally defined in a sidewall 208 and a selectively sealed by a slit valve to facilitate entry and egress of a substrate 400 from the processing chamber 200. An exhaust port 226 is defined in the chamber body 202 and couples the interior volume 206 to a vacuum pumping system 228. The vacuum pumping system 228 generally includes one or more pumps and throttle valves utilized to evacuate and regulate the pressure of the interior volume 206 of the processing chamber 200. In one embodiment, the vacuum pumping system 228 maintains the pressure inside the interior volume 206 at operating pressures typically between about 10 mTorr to about 500 Torr.

The lid 204 is sealingly supported on the sidewall 208 of the chamber body 202. The lid 204 may be opened to allow excess to the interior volume 206 of the processing chamber 200. The lid 204 includes a window 242 that facilitates optical process monitoring. In one embodiment, the window 242 is comprised of quartz or other suitable material that is transmissive to a signal utilized by an optical monitoring system 240 mounted outside the processing chamber 200.

The optical monitoring system 240 is positioned to view at least one of the interior volume 206 of the chamber body 202 and/or the substrate 400 positioned on a substrate support pedestal assembly 248 through the window 242. In one embodiment, the optical monitoring system 240 is coupled to the lid 204 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from is the EyeD® full-spectrum, interferometric metrology module, available from Applied Materials, Inc., of Santa Clara, Calif.

A gas panel 258 is coupled to the processing chamber 200 to provide process and/or cleaning gases to the interior volume 206. In the embodiment depicted in FIG. 2, inlet ports 232′, 232″ are provided in the lid 204 to allow gases to be delivered from the gas panel 258 to the interior volume 106 of the processing chamber 200. In one embodiment, the gas panel 258 is adapted to provide fluorinated process gas through the inlet ports 232′, 232″ and into the interior volume 206 of the processing chamber 200. In one embodiment, the process gas provided from the gas panel 258 includes at least a fluorinated and carbon gas, chlorine, and a carbon containing gas, an oxygen gas, a carbon containing gas, a nitrogen containing gas and a chlorine containing gas. Examples of fluorinated and carbon containing gases include CH₄, CHF₃ and CF₄. Other fluorinated gases may include one or more of C₂F, C₄F₆, C₃F₈ and C₅F₈. Examples of the oxygen containing gas include O₂, CO₂, CO, N₂O, NO₂, O₃, H₂O, and the like. Examples of the carbon containing gas include CO₂, CO, COS, CH₄, C₂H₆, C₂H₄ and the like. Examples of the nitrogen containing gas include N₂, NH₃, N₂O, NO₂ and the like. Examples of the chlorine containing gas include HCl, Cl₂, CCl₄, CHCl₃, CH₂Cl₂, CH₃Cl, and the like.

A showerhead assembly 230 is coupled to an interior surface 214 of the lid 204. The showerhead assembly 230 includes a plurality of apertures that allow the gases flowing through the showerhead assembly 230 from the inlet ports 232′, 232″ into the interior volume 206 of the processing chamber 200 in a predefined distribution across the surface of the substrate 400 being processed in the processing chamber 200.

A remote plasma source 277 may be optionally coupled to the gas panel 258 to facilitate dissociating gas mixture from a remote plasma prior to entering into the interior volume 206 for processing. A RF source power 243 is coupled through a matching network 241 to the showerhead assembly 230. The RF source power 243 typically is capable of producing up to about 3000 W at a tunable frequency in a range from about 50 kHz to about 13.56 MHz.

The showerhead assembly 230 additionally includes a region transmissive to an optical metrology signal. The optically transmissive region or passage 238 is suitable for allowing the optical monitoring system 240 to view the interior volume 206 and/or the substrate 400 positioned on the substrate support pedestal assembly 248. The passage 238 may be a material, an aperture or plurality of apertures formed or disposed in the showerhead assembly 230 that is substantially transmissive to the wavelengths of energy generated by, and reflected back to, the optical monitoring system 240. In one embodiment, the passage 238 includes a window 242 to prevent gas leakage through that the passage 238. The window 242 may be a sapphire plate, quartz plate or other suitable material. The window 242 may alternatively be disposed in the lid 104.

In one embodiment, the showerhead assembly 230 is configured with a plurality of zones that allow for separate control of gas flowing into the interior volume 206 of the processing chamber 200. In the embodiment FIG. 2, the showerhead assembly 230 as an inner zone 234 and an outer zone 236 that are separately coupled to the gas panel 258 through separate inlet ports 232′, 232″.

The substrate support pedestal assembly 248 is disposed in the interior volume 206 of the processing chamber 200 below the showerhead assembly 230. The substrate support pedestal assembly 248 holds the substrate 400 during processing. The substrate support pedestal assembly 248 generally includes a plurality of lift pins (not shown) disposed therethrough that are configured to lift the substrate 400 from the substrate support pedestal assembly 248 and facilitate exchange of the substrate 400 with a robot (not shown) in a conventional manner.

In one embodiment, the substrate support pedestal assembly 248 includes a mounting plate 262, a base 264 and an electrostatic chuck 266. The mounting plate 262 is coupled to the bottom 210 of the chamber body 202 includes passages for routing utilities, such as fluids, power lines and sensor leads, among other, to the base 264 and the electrostatic chuck 266. The electrostatic chuck 266 comprises at least one clamping electrode 280 for retaining the substrate 400 below the showerhead assembly 230. The electrostatic chuck 266 is driven by a chucking power source 282 to develop an electrostatic force that holds the substrate 400 to the chuck surface, as is conventionally known. Alternatively, the substrate 400 may be retained to the substrate support pedestal assembly 248 by clamping, vacuum or gravity.

At least one of the base 264 or electrostatic chuck 266 may include at least one optional embedded heater 276, at least one optional embedded isolator 274 and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, so to heat and/or cool the electrostatic chuck 266. The temperature of the electrostatic chuck 266 and the base 264 may be monitored using a plurality of temperature sensors 290, 292. The electrostatic chuck 266 may further comprise a plurality of gas passages (not shown), such as grooves, that are formed in a substrate supporting surface of the electrostatic chuck 266 and fluidly coupled to a source of a heat transfer (or backside) gas, such as He. In operation, the backside gas is provided at controlled pressure into the gas passages to enhance the heat transfer between the electrostatic chuck 166 and the substrate 400.

In one embodiment, the substrate support pedestal assembly 248 is configured as a cathode and includes electrode, such as the electrode 280, that is coupled to a plurality of RF bias power sources 284, 286. The RF bias power sources 284, 286 are coupled between the electrode 280 disposed in the substrate support pedestal assembly 248 and another electrode, such as the showerhead assembly 230 or ceiling (lid 204) of the chamber body 202. The RF bias power excites and sustains a plasma discharge formed from the gases disposed in the processing region of the chamber body 202.

In the embodiment depicted in FIG. 2, the dual RF bias power sources 284, 286 are coupled to the electrode 280 disposed in the substrate support pedestal assembly 248 through a matching circuit 288. The signal generated by the RF bias power sources 284, 286 is delivered through matching circuit 288 to the substrate support pedestal assembly 248 through a single feed to ionize the gas mixture provided in the plasma processing chamber 200, providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts. An additional bias power source 289 may be coupled to the electrode 280 to control the characteristics of the plasma.

In one mode of operation, the substrate 400 is disposed on the substrate support pedestal assembly 248 in the plasma processing chamber 200. A process gas and/or gas mixture is introduced into the chamber body 202 through the showerhead assembly 230 from the gas panel 258. The process gases are energized to form a plasma used to process the substrate 400. A vacuum pumping system 228 maintains the pressure inside the chamber body 202 while removing processing by-products.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing system 100 are handled through numerous signal cables.

FIG. 2 only shows one exemplary configuration of the various types of plasma processing chambers that can be used to practice the embodiments. For example, different types of microwave power, magnetic power and bias power can be coupled into the plasma chamber using different coupling mechanisms. In some applications, different types of plasma may be generated in a chamber different from the chamber in which the substrate is located, e.g., remote plasma source, and the plasma subsequently guided into the chamber using techniques known in the art.

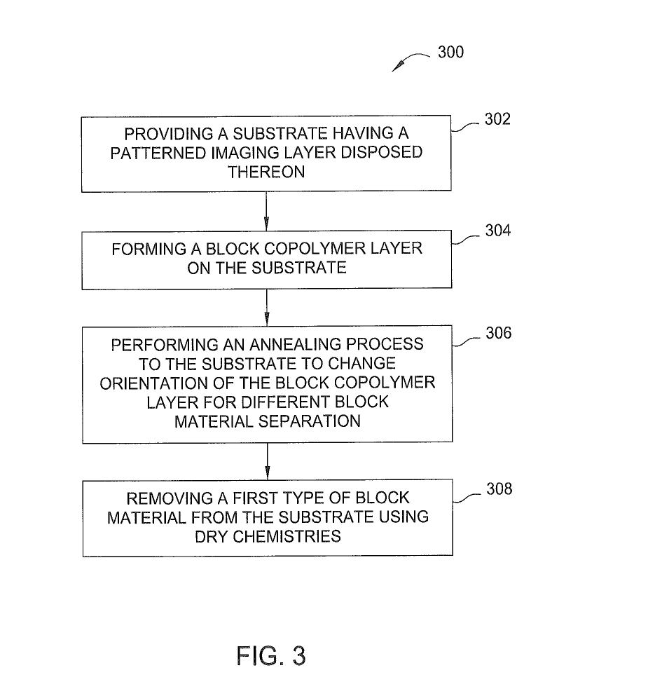

FIG. 3 illustrates a flow diagram of one embodiment of a method for performing a dry development process 300 to form a photoresist layer on the substrate to transfer features into the substrate using a directed self-assembly (DSA) of block copolymers (BCPs) process. The process 300 may be stored in memory 254 as instructions that executed by the controller 250 to cause the process 300 to be performed in an etching processing chamber, such as the processing chamber 200 depicted in FIG. 2 or other suitable processing reactors.

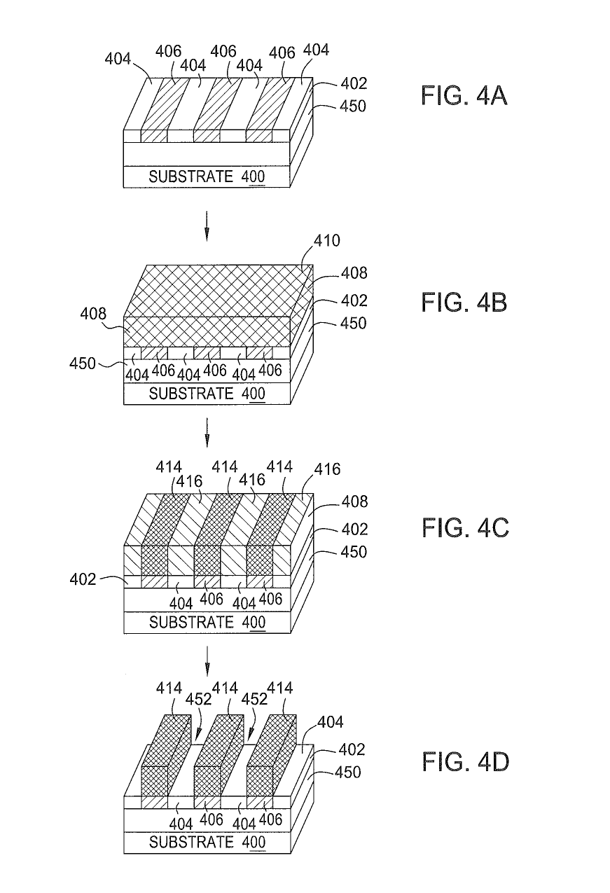

The process 300 begins at a block 302 by transferring a substrate, such as the substrate 400 depicted in FIG. 2, into the processing chamber 200 for processing. The substrate 400 may have a target material 450 which is to be patterned to have desired features to be transferred thereto, as shown in FIG. 4A. In one embodiment, the target material 450 may be a dielectric layer, a metal layer, a ceramic material, or other suitable material. In one embodiment, the target material 450 to be etched may be a dielectric material formed as a gate structure or a contact structure or an inter-layer dielectric structure (ILD), or an interconnection layer utilized in semiconductor manufacture. Suitable examples of the dielectric material include silicon oxide, silicon nitride, silicon oxynitride, silicon carbide, SiOC, SiOCN, amorphous carbon, nitride, titanium nitride, composite of oxide and nitride, at least one or more oxide layers sandwiching a nitride layer, and combinations thereof, among others. The dielectric material may also be a high-k material having a dielectric constant greater than 4. Suitable examples of the high-k materials include hafnium dioxide (HfO₂), zirconium dioxide (ZrO₂), hafnium silicon oxide (HfSiO₂), hafnium aluminum oxide (HfAlO), zirconium silicon oxide (ZrSiO₂), tantalum dioxide (TaO₂), aluminum oxide, aluminum doped hafnium dioxide, bismuth strontium titanium (BST), and platinum zirconium titanium (PZT), among others, In another embodiment, the target material 450 to be etched may be a metal material formed as an inter-metal dielectric structure (IMD) or other suitable structure. Suitable examples of metal of the target material 450 include Cu, Al, W, Ni, Cr, or the like. In one particular embodiment, the target material 450 is an amorphous carbon layer.

In the embodiment wherein the target material 450 is not present, other materials, layers, and/or structures subsequently may be directly formed on the substrate 400 as needed.

The substrate 400 may have a substantially planar surface, an uneven surface, or a substantially planar surface having a structure formed thereon. The substrate 400 may be a material such as crystalline silicon (e.g., Si<100>or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 400 may have various dimensions, such as 200 mm, 300 mm, 450 mm or other diameter wafers, as well as, rectangular or square panels. Unless otherwise noted, embodiments and examples described herein are conducted on substrates with a between about 200 mm and about 500 mm diameter substrate. In the embodiment wherein a SOI structure is utilized for the substrate 400, the substrate 400 may include a buried dielectric layer disposed on a silicon crystalline substrate. In the embodiment depicted herein, the substrate 400 may be a crystalline silicon substrate.

A patterning defining layer 402 is disposed on the substrate 400, as shown in FIG. 4A. The patterning defining layer 402 may have a first group of regions 406 and a second group of regions 404 formed thereon. Although the embodiment depicted in FIG. 4A illustrates the first group of regions 406 and the second group of regions 404 in strip line form, it is noted that the first group of regions 406 and the second group of regions 404 formed in the patterning defining layer 402 may be in any form, such as circular, columnar, wavy lines or any suitable forms as needed.

In one embodiment, the first group of regions 406 and the second group of regions 404 may be formed in the patterning defining layer 402 by a light activation process, as described above, using an light energy to change film properties, roughness, topography at different regions of the patterning defining layer 402 to form the first groups of regions 406, leaving the non-activated/untreated area as the second group of regions 404. Alternatively, the first groups of regions 406 and the second group of regions 404 may be formed by a series of lithography and etching processes, or by forming additional materials on the substrate 400 to form additional patterns which may be capable of inducing phase/orientation change process to the block copolymers (BCPs) 408 during the subsequent annealing process. It is noted that the first groups of regions 406 and the second group of regions 404 provided in the patterning defining layer 402 may be formed in any suitable technique as needed.

At block 304, a block copolymer deposition process is performed to deposit a block copolymer (BCP) layer 408 on the patterning defining layer 402. In one embodiment, the block copolymer (BCP) layer 408 may be deposited on the substrate 400 by spin-on coating, spray coating, aerosol coating, or other suitable coating techniques conventional available.

In one embodiment, the block copolymers (BCPs) comprising the block copolymer (BCP) layer 408 may include at least two polymers, for example polymer A and polymer B. Thus, the block copolymer (BCP) layer 408 can comprise a first block component labeled as polymer A and a second block component labeled as polymer B, represented by the formula (AB)ₙ, wherein the n is any integer greater than or equal to 1.

Components of the first polymer A are configured to have an affinity for the first group of regions 406 so as to enable the occurrence of the directed self-assembly process for the first polymer A turning into columnar blocks, e.g., strip lines when viewed in two dimensions, perpendicular to the first group of regions 406 disposed on the substrate 400 during the subsequent annealing process. The second polymer B is then separated and segregated in the second group of regions 404. Suitable materials for the block copolymers (BCPs) includes, but not limited to, poly(styrene-block-methylmethacrylate) (PS-b-PMMA), poly(ethylene oxide-block-isoprene) (PEO-b-PI), poly(ethylene oxide-block-butadiene) (PEO-b-PBD), poly(ethylene oxide-block-styrene) (PEO-b-PS), poly(ethylene oxide-block-methylmethacrylate) (PEO-b-PMMA), poly(ethyleneoxide-block-ethylethylene) (PEO-b-PEE), poly(styrene-block-vinylpyridine) (PS-b-PVP), poly(styrene-block-isoprene) (PS-b-PI), poly(styrene-block-butadiene) (PS-b-PBD), poly(styrene-block-ferrocenyldimethylsilane) (PS-b-PFS), poly(butadiene-block-vinylpyridine) (PBD-b-PVP), poly(isoprene-block-methyl methacrylate) (PI-b-PMMA), poly(styrene-block-dymethylsiloxane) (PS-b-PDMS), or Poly(styrene-b-lactide) (PS-b-PLA), among others. In a particular embodiment depicted herein, the block copolymers (BCPs) comprising the block copolymer (BOP) layer 408 disposed on the substrate 400 is poly(styrene-block-methylmethacrylate) (PS-b-PMMA), and may include poly styrene (PS) as polymer A and poly methylmethacrylate (PMMA) as polymer B.

At block 306, after the block copolymer (BCP) layer 408 is deposited on the substrate 400, a thermal annealing process is performed. During annealing, the thermal energy provided in the annealing process promotes sufficient phase separation between the two or more different block components of the block copolymers (BCPs) as to promote directed self-assembly of the block components into an ordered pattern with repeated structural unit based on the guidance defined by the underlying patterning defining layer 402. In the embodiment depicted in FIG. 4C, during the annealing process, the polymer A, for example polystyrene (PS), is aggregated over the first group of regions 406 defined in the patterning defining layer 402, forming strip-line blocks 414 of PS in the block copolymer (BCP) layer 408. In the mean while, the polymer B, for example polymethylmethacrylate (PMMA), is then being separated and grouped onto the second group of regions 404, forming the strip-line blocks 416 of PMMA in the layer of the block copolymers (BCPs) 408. Although the block copolymer (BCP) layer 408 described herein is transitioned into a first and a second groups of strip-line blocks 414, 416 with polymers PS and PMMA respectively, it is noted that the block copolymer (BCP) layer 408 may be configured to form different shape or numbers of groups including using different monomers in any form, such circular, polygonal, spherical, cylindrical, pillar, or any other suitable shape s as needed.

The annealing process may be performed in a baking oven, a curing oven, curing plate, or an annealing chamber as need to provide thermal energy to the substrate 400 to effect the phase/origination change of the block copolymer (BCP) layer 408. In one embodiment, the annealing process performed at block 306 may maintain at a temperature range between about 150 degrees Celsius and about 325 degrees Celsius, such as between about 200 degrees Celsius and about 280 degrees Celsius. During the thermal annealing process, a gas mixture may be optionally supplied into the annealing chamber. Suitable gases that may be used during the annealing process include dichloroethane (CH₂Cl₂), or gas vapor from suitable organic solvent, such as toluene. The annealing process may be performed for between about 1 hour and about 24 hours.

At block 308, a dry development process, e.g., an plasma etching process, is performed to remove the second group strip-line blocks 416 of PMMA from the substrate 400, as shown in FIG. 4D, leaving predominately the first group of strip-line blocks 414 of PS on the substrate 400 as an etching mask for the subsequent pattern transfer process. The dry development process is performed by supplying an etching gas mixture including certain chemistries that have high selectivity for the polymer A over the polymer B PS vs. PMMA) so that etching gas mixture predominantly etches the polymer B of PMMA rather than etching the polymer A of PS, removing predominately the second group strip-line blocks 416 from the substrate and forming openings 452 which expose the underlying regions 404.

In one embodiment, the etching gas mixture includes, but not limited to, a carbon containing gas optionally accompanying by an oxygen containing gas and/or an inert gas. Examples of the carbon containing gas include CO₂, CO, CH₄, C₂H₄, C₂H₆, CH₂F₂, COS and the like. Examples of the oxygen containing gas include O₂, NO, N₂O, CO₂, CO, COS, and the like. Alternatively, a carrier gas, such as N₂, Ar or He, may also be incorporated with the first trimming gas into the etch processing chamber.

It is believed that the carbon containing gas is configured to be a mild oxidizer in a lower power plasma etching process, such as a source RF power no more than 110 Watts, so that it is easy to control and maintain vertical profile and surface roughness of the profile of the first group of strip-line blocks 414 of PS remaining on the substrate 400. The UV emission generated in the plasma during the dry development process is controlled within wavelength between 200 nm and about 380 nm, which is believed to help smoothing the surface roughness and profile of the first group of strip-line blocks 414 of PS remaining on the substrate 400. Furthermore, the selectivity for the second group of strip-line blocks 416 of PMMA over the group of strip-line blocks 414 of PS is also improved from about 20:1 to about 40:1 or greater. Therefore, by utilizing carbon containing gas supplied in the etching gas mixture instead of conventional oxygen containing gas, photoresist defects, such as line edge roughness, line collapse, profile deformation or other types of defects may be substantially eliminated while line feature integrity, vertical line profile and etching selectivity may be improved.

In one embodiment, the carbon containing gas supplied in the etching gas mixture is CO₂, COS or CH₄. In some embodiments, two or more carbon containing gas or an oxygen containing gas may also be supplied in the etching gas mixture. In one particular embodiment, the carbon containing gas and the oxygen containing gas supplied in the etching gas mixture are CO₂ and O₂ or CO₂ and COS. In one embodiment, the CO₂ gas and the O₂ gas may be supplied in the etching gas mixture at a ratio between about 100:1 and about 100:10, such as between about 100:1 and about 100:5. The CO₂ gas flowed into the chamber at a rate between about 200 sccm to about 400 sccm. The O₂ may be supplied at a rate between about 5 sccm and about 10 sccm. A carrier gas, such as Ar, He or N₂, may be supplied in the gas mixture between about 100 sccm and about 200 sccm.

In another embodiment, the CO₂ gas and the COS gas may be supplied in the etching gas mixture at a ratio between about 100:1 and about 100:10, such as between about 100:1 and about 100:3. The CO₂ gas flowed into the chamber at a rate between about 200 sccm to about 400 sccm. The COS may be supplied at a rate between about 5 sccm and about 10 sccm. A carrier gas, such as Ar, He or N₂, may be supplied in the gas mixture between about 100 sccm and about 200 sccm. The COS gas supplied in the etching gas mixture alone with the CO₂ gas may improve the selectivity for the polymer PMMA over the polymer PS and thus achieve desired feature profile after the dry development process for CO₂ gas based etching gas mixture. The selectivity for the polymer PMMA over the polymer PS is improved from about 40:1 to about 50:1 or greater.

Several process parameters are regulated while the etching mixture at block 308 supplied into the processing chamber. In one embodiment, the chamber pressure in the presence of the etching gas mixture is regulated between about 10 mTorr to about 15 mTorr. A substrate temperature may be maintained between about 10 degrees Celsius to about 500 degrees Celsius, such as about 20 degrees Celsius.

A low range of source RF power may be applied to maintain gentle plasma formed from the etching process gas. For example, a RF source power of no more than about 110 Watts, such as between about 90 Watts to about 110 Watts, may be applied to maintain gentle and mild plasma inside the etch chamber without aggressively attacking the substrate and polymer comprising the strip-line block 414. In some embodiment, the source RF power may not be used only maintain bias RF power to gently etch the substrate 400. The RF source power may have a frequency of about 60 MHz. A bias RF power of no more than 70 Watts, such as between about 50 Watts to about 70 Watts, may be applied to maintain gentle and mild plasma inside the etch chamber. The RF bias power may have a frequency of about 13.56 MHz, such as between about 13 MHz and about 14 MHz.

After the second group of the strip-line blocks 416 of PMMA is etched away from the substrate 400, a main etching process may then be performed to etch the underlying target material 450 along with the patterning defining layer 102 using the remaining first group of strip-line blocks 414 of PS on the substrate 400 as an etching mask. As such, features defined by the first group of strip-line blocks 414 of PS is then transferred into the underlying target material 450 with desired profile and critical dimension.

Thus, embodiments of methods and an apparatus for forming a patterned photoresist layer on a substrate as an etching mask using a directed self-assembly (DSA) of block copolymers (BCPs) process are provided. The dry development process as utilized to etch the block copolymers (BCPs) includes a carbon containing gas that advantageously provides a gentle etching process to provide high etching selectivity to different polymers in the block copolymers (BCPs), forming a patterned photoresist layer with desired line integrity and vertical profile so the subsequent etching process may accurately transfer features to the underlying layer by using the patterned photoresist layer as an etching mask.

While the foregoing is directed to embodiments of the methods and apparatus, other and further embodiments may be devised without departing from the basic scope thereof, and the scope thereof is determined by the claims that follow.

What is claimed is:

1. A method for performing a dry development process, comprising:
transferring a substrate having a layer of block copolymers disposed thereon into an etching processing chamber, wherein at least a first type and a second type of polymers comprising the block copolymers are aggregated into a first group of regions and a second group of regions on the substrate;
supplying an etching gas mixture including at least a carbon containing gas into the etching processing chamber; and
predominately etching the second type of the polymers disposed on the second groups of regions on the substrate in the presence of the etching gas mixture.

2. The method of claim 1, wherein supplying the etching gas mixture further comprises:
supplying a source RF power no more than 110 Watts.

3. The method of claim 1, wherein supplying the etching gas mixture further comprises:
supplying a bias RF power no more than 70 Watts.

4. The method of claim 1, wherein the first type and the second type of polymers are selected from a group consisting of poly(styrene-block-methylmethacrylate) (PS-b-PMMA), poly(ethylene oxide-block-isoprene) (PEO-b-PI), poly(ethylene oxide-block-butadiene) (PEO-b-PBD), poly(ethylene oxide-block-styrene) (PEO-b-PS), poly(ethylene oxide-block-methylmethacrylate) (PEO-b-PMMA), poly(ethyleneoxide-block-ethylethylene) (PEO-b-PEE), poly(styrene-block-vinylpyridine) (PS-b-PVP), poly(styrene-block-isoprene) (PS-b-PI), poly(styrene-block-butadiene) (PS-b-PBD), poly(styrene-block-ferrocenyldimethylsilane) (PS-b-PFS), poly(butadiene-block-vinylpyridine) (PBD-b-PVP), poly(isoprene-block-methyl methacrylate) (PI-b-PMMA), poly(styrene-block-dymethylsiloxane) (PS-b-PDMS), and Poly(styrene-b-lactide) (PS-b-PLA).

5. The method of claim 1, wherein the block copolymers includes poly(styrene-block-methylmethacrylate).

6. The method of claim 1, wherein the first type of polymer is polystyrene and the second type of polymer is poly methylmethacrylate.

7. The method of claim 1, wherein the carbon containing gas is selected from a group consisting of CO₂, CO, COS, CH₄, C₂H₄ and O₂ H₆.

8. The method of claim 1, wherein the etching gas mixture has a selectivity greater than 40 for the first type of the polymer over the second type of the polymer.

9. The method of claim 1, wherein the substrate further comprises a patterning defining layer disposed underneath the layer of block copolymers defining the first and the second group of regions aligned with the first type and the second type of the polymers disposed thereon.

10. The method of claim 1, further comprising:
forming a patterned etch mask on the substrate from the first type of the polymers remaining on the substrate.

11. The method of claim 1, wherein the first type and the second type of the polymers are formed in strip line blocks.

12. The method of claim 1, comprising:
annealing the substrate prior to transferring into the etching processing chamber, the annealing process aggregating the first type of polymers separated from and the second type of the polymers.

13. The method of claim 1, wherein the etching gas mixture further includes an inert gas.

14. A method for forming a photoresist layer using a directed self-assembly process comprising:
disposing a layer of block copolymers on a substrate, wherein the block copolymers include at least a first type of polymer and a second type of polymer;
performing an annealing process on the layer of block copolymers, the annealing process separating the first type of polymer from the second type of the polymer;
supplying an etching gas mixture including at least a carbon containing gas onto the substrate; and
selectively etching the second type of polymer in the presence of the etching gas mixture.

15. The method of claim 14, further comprising:
forming a photoresist layer as an etching mask on the substrate from the second type of polymer remaining on the substrate after etching in the presence of the etching gas mixture.

16. The method of claim 14, the carbon containing gas is selected from a group consisting of CO₂, CO, COS, CH₄, C₂H₄ and O₂H₆.

17. The method of claim 14, wherein supplying the etching gas mixture further comprises:
supplying a bias RF power no more than 70 Watts.

18. The method of claim 14, wherein the first type and the second type of polymers are selected from a group consisting of poly(styrene-block-methylmethacrylate) (PS-b-PMMA), poly(ethylene oxide-block-isoprene) (PEO-b-PI), poly(ethylene oxide-block-butadiene) (PEO-b-PBD), poly(ethylene oxide-block-styrene) (PEO-b-PS), poly(ethylene oxide-block-methylmethacrylate) (PEO-b-PMMA), poly(ethyleneoxide-block-ethylethylene) (PEO-b-PEE), poly(styrene-block-vinylpyridine) (PS-b-PVP), poly(styrene-block-isoprene) (PS-b-PI), poly(styrene-block-butadiene) (PS-b-PBD), poly(styrene-block-ferrocenyldimethylsilane) (PS-b-PFS), poly(butadiene-block-vinylpyridine) (PBD-b-PVP), poly(isoprene-block-methyl methacrylate) (PI-b-PMMA), poly(styrene-block-dymethylsiloxane) (PS-b-PDMS), and Poly(styrene-b-lactide) (PS-b-PLA).

19. The method of claim 14, wherein the first type of polymer is polystyrene and the second type of polymer is poly methylmethacrylate.

20. A method for forming a photoresist layer by a dry development process utilizing a directed self-assembly of block copolymers process comprising:
forming a layer of block copolymers including polystyrene and polymethylmethacrylate on a substrate wherein the polystyrene and the polymethylmethacrylate are formed in strip line forms and separately arranged in a first group and a second group of regions defined on the substrate;
supplying an etching gas mixture including at least a carbon containing gas;
applying a RF bias power no more than 70 Watts; and
selectively etching the polymethylmethacrylate disposed on the second groups of region from the substrate in the presence of the etching gas mixture.
